(19) United States
(12) Patent Application Publication
(10) Pub. No.: US 2015/0214315 A1
(43) Pub. Date: Jul. 30, 2015

(54) Non-Volatile Memory and Methods for Producing Same

(71) Applicant: Xinnova Technology Limited, Beijing (CN)

(72) Inventors: Der-Tsyr Fan, Beijing (CN); Chih-Ming Chen, Beijing (CN); Jung-Chang Lu, Beijing (CN)

(73) Assignee: Xinnova Technology Limited

(21) Appl. No.: 14/595,864

(22) Filed: Jan. 13, 2015

(30) Foreign Application Priority Data
Jan. 28, 2014 (CN) 201410042003.1

(51) Int. Cl. H01L 29/423; H01L 27/115; H01L 29/66; H01L 29/788

(52) U.S. Cl. CPC H01L 29/42324; H01L 29/788; H01L 27/11521; H01L 29/66825

(57) ABSTRACT

A non-volatile memory unit includes a substrate on which a source diffusion region and a drain diffusion region are formed. A first dielectric layer and a tunnel dielectric layer are formed between the source diffusion region and the drain diffusion region, are respectively on the drain diffusion region side and the source diffusion region side, and are connected to each other. A select gate is formed on the first dielectric layer. A source insulating layer is formed on the source diffusion region. The tunnel dielectric layer extends to the source diffusion region and is connected to the source insulating layer. A floating gate is formed on a face of the tunnel dielectric layer and a face of the thicker source insulating layer. A control gate is formed on the floating gate. The control gate and the floating gate are insulating to each other by the second dielectric layer.

### BACKGROUND OF THE INVENTION

The present invention relates to a structure of an integrated circuit component and its producing methods and, more particularly, to a non-volatile memory and methods for producing the non-volatile memory.

Non-volatile memories have advantages of small volumes, light weights, low power consumption, and prevention of loss of data resulting from power interruption and are, thus, suitable for applications in hand-held electronic devices. Following the popularization of hand-held electronic devices, non-volatile memories have widely been used as multimedia storage devices or used for maintaining normal operation of electronic systems. The need of non-volatile memories increases every year, and the costs and prices decrease, which is a positive cycle for non-volatile memories. Thus, non-volatile memories have become one of the most important products in the semiconductor industry.

U.S. Pat. No. 4,698,787 discloses a non-volatile memory unit of a stack-gate non-volatile memory structure including a floating gate. When the memory undergoes an operation of writing “1”, a sufficient amount of electrons is trapped in the floating gate by hot-electron injection, such that the status of the memory unit is “1”. When the memory undergoes an operation of writing “0” or erasing, electrons are removed from the floating gate by Fowler-Nordheim tunneling, such that the status of the memory unit is “0”. Since the status of the memory unit depends on whether a sufficient amount of electrons is trapped in the floating gate, the status of the memory unit can be maintained even if the power source is removed and is, thus, referred to as a non-volatile memory.

However, the stack-gate non-volatile memory still have the following disadvantages. Firstly, an over erasure effect exists. When the memory unit undergoes the erasing operation, excessive electrons could be removed from the floating gate, resulting in a negative threshold voltage of an equivalent transistor component in the memory unit; namely, the memory unit is normally in a conductive state that leads to unnecessary leakage current. Secondly, a larger operating current is required during the erasing operation. When the memory undergoes the erasing operation, the source voltage is much larger than the voltage of the floating gate and, thus, results in a gate-induced drain leakage (GIDL) effect, leading to leakage current from the source to the substrate. As a result, an external power source more powerful in providing current is required in the operation, leading to difficulties in integration of the whole circuit. Furthermore, to reduce the extent of leakage, the source is in the form of a lightly-doped drain structure.

However, as the processes are more and more advanced and the size becomes smaller and smaller, the lightly-doped drain is apt to cause a punch-through effect. Thus, when a stack-gate non-volatile memory is produced by a process for less than 0.2 μm technology node, the lightly-doped drain structure is replaced by a deep N-well to isolate the source from the substrate to avoid leakage. However, in a memory matrix comprised of stack-gate non-volatile memories, a plurality of memory units shares the deep N-well to save the area. Due to the structural limitation, the memory units sharing the deep N-well must simultaneously undergo the erasing operation, which sacrifices the operational flexibility of the circuit. Lastly, during writing of “1”, the tunneling probability of electrons is low, because the electric field of the channel is stronger. Thus, a stronger current is required in the operation for increasing the operating speed.

U.S. Pat. No. 5,338,952 and U.S. Pat. No. 5,414,286 disclose a split-gate non-volatile memory. In comparison with the above conventional technique, the split-gate non-volatile memory has an additional select gate. Since conduction of the channel in an equivalent transistor component of the non-volatile memory unit requires a positive voltage at both the floating gate and the select gate to be larger than the threshold voltage, the drawback of normal leakage can be avoided by controlling the voltage of the selective gate. However, the floating gate and the selective gate do not overlap, such that the area of the chip is larger. Aside from this, the principles of writing operation and erasing operation are the same as a stack-gate non-volatile memory. U.S. Pat. No. 7,009,144, U.S. Pat. No. 7,199,424, and U.S. Pat. No. 7,407,857 also disclose a split-gate non-volatile memory structure in which a stepped structure is provided at a bottom of the floating gate. In comparison with the above conventional techniques, this invention has two advantages. Firstly, in comparison with the conventional technique of the above split-gate non-volatile memory, the wedge structure can reduce the degree of capacitor coupling between the floating gate and the source, such that a larger portion of the voltage applied to a control gate can be coupled to the floating gate. Thus, when the memory unit undergoes the writing or erasing operation, a lower supply voltage can be used. Secondly, in comparison with the above two conventional techniques, the wedge structure can reduce the intensity of the electric field between the source and the floating gate to reduce leakage from the source to the substrate, avoiding processes using lightly-doped drains or deep N-wells. Thus, the area can be further reduced to cut the costs. However, during conduction of an equivalent transistor component of the non-volatile memory unit, the magnitude of the conduction current is decided by a thicker gate dielectric layer formed by the wedge structure, such that the change in the conduction current is larger and, thus, adversely affects the yield of the memories. Furthermore, the thicker tunnel dielectric layer of the stepped floating gate is liable to cause a short circuit between the drain and the source, resulting in great limitation to further miniaturization of the structure.

Furthermore, in the above split-gate non-volatile memory structures, since multiple polycrystalline silicon etching processes are involved in formation of the floating gate during implementation of U.S. Pat. No. 5,338,952, U.S. Pat. No. 5,414,286, U.S. Pat. No. 7,009,144,U.S. Pat. No. 7,199,242, and U.S. Pat. No. 7,407,857, residuals of polycrystalline silicon resulting from excessive etching in through-holes in the surface of the drain or resulting from shallow etching occur easily. Thus, it is difficult to stably maintain the integrity of the non-volatile memory and, thus, reduces the practicability of the split-gate non-volatile memory.

### BRIEF SUMMARY OF THE INVENTION

An objective of the present invention is to overcome the drawbacks of the conventional techniques by providing a non-volatile memory which can reduce the leakage current resulting from the gate-induced drain leakage effect, which can provide good control on the magnitude of the conduction current during conduction, and which can further cooperate with advanced processes to reduce the per unit area of the memory unit and to provide integrity of the product.

The technical solution for achieving the above objective is a non-volatile memory unit according to the present invention including a substrate having an upper surface. The substrate further includes a source diffusion region and a drain diffusion region in the substrate. A first dielectric layer is formed on the upper surface of the substrate and is located on the drain diffusion region side. A tunnel dielectric layer is formed on the upper surface of the substrate and is located on the source diffusion region side. The tunnel dielectric layer includes a lower face covering a portion of the source diffusion region. A source insulating layer is formed on an upper surface of the source diffusion region of the substrate and includes a lower face. An entire area of the lower face of the source insulating layer covers the source diffusion region. A select gate is formed on the first dielectric layer. A floating gate is formed on a face of the tunnel dielectric layer and a face of the source insulating layer. A portion of the floating gate is located on the tunnel dielectric layer covering a portion of the source diffusion region. A second dielectric layer is formed on a face of the floating gate. A control gate is formed on the floating gate. The control gate and the floating gate are insulating to each other by the second dielectric layer.

The source diffusion region can be a gradually diffused doped structure.

The first dielectric layer can have a thickness of 0.5-10 nm.

The tunnel dielectric layer can have a thickness of 5-15 nm.

The source insulating layer can have a thickness of 10-30 nm and can be thicker than a thickness of the tunnel dielectric layer.

The present invention further provides a method for producing a non-volatile memory unit. The method includes:

providing a substrate, with the substrate including an upper surface;

forming a first dielectric layer on the upper surface of the substrate;

forming a select gate on the first dielectric layer;

forming a select gate sidewall insulating layer, and forming a tunnel dielectric layer on the upper surface of the substrate at a location not covered by the select gate;

forming a self-aligned source dope blocking layer;

forming a source diffusion region by doping;

removing the self-aligned source dope blocking layer; forming a tunnel dielectric layer and a source insulating layer on a face of the source doped region by silicon oxidation, with the source insulating layer thicker than the tunnel dielectric layer, with a lightly-doped region of the source diffusion region formed at a junction between the tunnel dielectric layer and the source insulating layer and covering a portion of the tunnel dielectric layer;

forming a self-aligned floating gate on the tunnel dielectric layer and the source insulating layer;

forming a second dielectric layer on the floating gate; and

forming a control gate on the second dielectric layer, with a portion of the control gate located in a space of a channel structure of the second dielectric layer.

The source diffusion region can be a gradually diffused doped structure.

The first dielectric layer can have a thickness of 0.5-10 nm.

The tunnel dielectric layer can have a thickness of 5-12 nm.

The source insulating layer can have a thickness of 10-30 nm and is thicker than a thickness of the tunnel dielectric layer.

The self-aligned source dope blocking layer can be made of silicon nitride.

Formation of the source diffusion region by doping can be accomplished by implantation.

Furthermore, the present invention provides a method for producing a non-volatile memory unit. The method includes:

providing a substrate, with the substrate including an upper surface;

forming a first dielectric layer on the upper surface of the substrate;

forming a select gate on the first dielectric layer;

forming a select gate sidewall insulating layer, and forming a tunnel dielectric layer on the upper surface 1a of the substrate at a location not covered by the select gate;

forming a self-aligned source dope blocking layer;

forming a source diffusion region by doping;

forming a source insulating layer on a face of the source doped region by silicon oxidation;

removing the self-aligned source dope blocking layer;

forming a tunnel dielectric layer, with a lightly-doped region of the source diffusion region formed at a junction between the tunnel dielectric layer and the source insulating layer and covering a portion of the tunnel dielectric layer;

forming a self-aligned floating gate on the tunnel dielectric layer and the source insulating layer;

forming a second dielectric layer on the floating gate; and

forming a control gate on the second dielectric layer, with a portion of the control gate located in a space of a channel structure of the second dielectric layer.

The source diffusion region can be a gradually diffused doped structure.

The first dielectric layer can have a thickness of 0.5-10 nm.

The tunnel dielectric layer can have a thickness of 5-12 nm.

The source insulating layer can have a thickness of 10-30 nm and can be thicker than a thickness of the tunnel dielectric layer.

The self-aligned source dope blocking layer can be made of silicon nitride.

Formation of the source diffusion region by doping can be accomplished by implantation.

The advantages of the present invention are that the thickness of the dielectric layer between the floating gate and the source doped region of the non-volatile memory unit and the repairing the substrate surface defects (resulting from the doping procedure) by oxidation of the silicon substrate are automatically adjusted by the doping concentration of the source diffusion, such that when the non-volatile memory undergoes an erasing operation, the horizontal and vertical electric filed intensity between the source and the p-typed silicon substrate can effectively be reduced. Thus, the substrate defects triggering the source leakage can be sufficiently reduced by oxidation annealing, thereby reducing the leakage current from the source diffusion region to the p-type silicon substrate resulting from gate-induced drain leakage. The current supply demand of power source is reduced to permit easy achievement of integration of the whole circuit.

Furthermore, in the structure of this split-gate type non-volatile memory unit, the thicker source insulating layer can permit multiple polycrystalline silicon etching for forming the floating gate and can protect the drain diffusion surface and the source diffusion surface. The integrity of the non-volatile memory unit can be maintained during more etching processing for removing the residuals of polycrystalline silicon between the floating gates. Furthermore, this improvement also permits the area of the non-volatile memory unit to be further reduced under cooperation with advanced processes, further reducing the costs and increasing the yield.

The present invention will become clearer in light of the following detailed description of illustrative embodiments of this invention described in connection with the drawings.

### DESCRIPTION OF THE DRAWINGS

FIG. 1 is a diagrammatic cross sectional view of a non-volatile memory unit according to the present invention.

FIG. 2a is a diagrammatic view illustrating formation of a select gate and a first insulating layer by an example of a method for producing a non-volatile memory unit according to the present invention.

FIG. 2b is a diagrammatic view illustrating formation of a sidewall barrier layer on the structure of FIG. 2a.

FIG. 2c is a diagrammatic view illustrating formation of an n-type doped region of a source on the structure of FIG. 2b.

FIG. 2d is a diagrammatic view illustrating formation of a tunnel oxidation layer and a source insulating layer on the structure of FIG. 2c.

FIG. 2e is a diagrammatic view illustrating formation of a polycrystalline silicon layer on the structure of FIG. 2d and after reactive ion etching.

FIG. 2f is a diagrammatic view illustrating formation of a floating gate, a drain diffusion region and a source diffusion region on the structure of FIG. 2e.

FIG. 2g is a diagrammatic view illustrating formation of a second dielectric layer on the structure of FIG. 2f.

FIG. 2h is a diagrammatic view illustrating formation of a control gate on the structure of FIG. 2g.

FIG. 3a is a diagrammatic view illustrating formation of a select gate and a first insulating layer by another example of a method for producing a non-volatile memory unit according to the present invention.

FIG. 3b is a diagrammatic view illustrating formation of a sidewall barrier layer on the structure of FIG. 3a.

FIG. 3c is a diagrammatic view illustrating formation of an n-type doped region of a source on the structure of FIG. 3b.

FIG. 3d is a diagrammatic view illustrating formation of source side sacrificial oxide on the structure of FIG. 3c.

FIG. 3e is a diagrammatic view illustrating removal of residual oxidation layer from a substrate and removal of a portion of the source insulating layer from the structure of FIG. 3d.

FIG. 3f is a diagrammatic view illustrating formation of a tunnel oxidation layer and a source insulating layer on the structure of FIG. 3e.

FIG. 3g is a diagrammatic view illustrating formation of a polycrystalline silicon layer on the structure of FIG. 3f and after reactive ion etching.

FIG. 3h is a diagrammatic view illustrating formation of a control gate on the structure of FIG. 3g.

### REFERENCE NUMBER

1 p-type substrate

1a upper surface

3 select gate

4 first insulating layer

5a tunnel dielectric layer

5b source insulating layer

6 source side sacrificial oxide

7 polycrystalline silicon layer

8 floating gate

9 drain diffusion region

10 source diffusion region

11 second dielectric layer

12 control gate

13 first dielectric layer

15 sidewall barrier layer of silicon nitride

17 composite sidewall insulating layer of silicon dioxide or silicon nitride

18 sidewall barrier layer of silicon dioxide or silicon nitride

### DETAILED DESCRIPTION OF THE INVENTION

The present invention will be further described by way of examples in connection with the accompanying drawings.

The technical terms in the following description are used in reference to the idioms in the art. Some of the terms are explained or defined in the specification, and such explanation or definition in the specification should be based to interpret these terms. Furthermore, on the premise of practicability, the terms “on”, “under”, “at”, etc. used in the specification refers to directly or indirectly “on” or “under” an object or a reference object and directly or indirectly “at” an object or a reference object. The term “indirect” used herein refers to the existence of an intermediate object or a physical space. On the premise of practicability, the terms “contiguous” and “between” used herein refers to two objects or two reference objects between which an intermediate object or a space exists or does not exist. Furthermore, in the following description related to semiconductor processes, the terms common in the semiconductor processing field, such as the techniques of “formation of an oxidation layer”, “lithography”, “etching”, “cleaning”, “diffusion”, “ion implantation”, “chemical and physical vapor deposition”, will not be described to avoid redundancy if these terms do not involve the technical features of the present invention. Furthermore, the shape, size, and proportion of the components in the figures are illustrative only and are related to the parameters and processing capability mentioned in the specification to provide ease of understanding of the present invention by a person having ordinary in the art, rather than limiting the embodying scope of the present invention. Furthermore, the producing method mentioned in the specification is merely related to production of a single non-volatile memory unit. In fact, a person having ordinary skill in the art can use conventional techniques to implement an industrially applicable non-volatile memory matrix comprised of a plurality of non-volatile memory units.

FIG. 1 is a diagrammatic cross sectional view of a non-volatile memory unit according to the present invention.

Please refer to FIG. 1 showing two non-volatile memory units symmetric to each other. Description of the non-volatile memory unit at the left part of the figure will be set forth. The non-volatile memory unit includes a substrate that is generally a p-type silicon substrate 1. The p-type silicon substrate 1 includes an upper surface 1a. In the p-type silicon substrate 1, a drain diffusion region 9 is formed by an n-type doped layer, and a source diffusion region 10 is formed by another n-type doped layer. The source diffusion region 10 includes a lightly-doped region 10a that is a lightly-doped n-type region (source lightly n-doped diffusion). The drain diffusion region 9 is not contiguous to the source diffusion region 10.

As shown in FIG. 1, the non-volatile memory unit further includes a first dielectric layer 13, a tunnel dielectric layer 5a, a source insulating layer 5b, a select gate 3, a first insulating layer 4, a floating gate 8, and a control gate 12.

The first dielectric layer 13 is a gate dielectric layer and is generally an oxidation layer. The first dielectric layer 13 is formed on the upper surface 1a of the p-type silicon substrate 1. A thickness of the first dielectric layer 13 is 0.5-10 nm. The thickness of the first dielectric layer 13 can be equal to the thickness of a dielectric layer of any logic gate.

The tunnel dielectric layer 5a is generally a tunnel insulating layer of silicon dioxide and is formed between the first dielectric layer 13 and the source diffusion region 10. A thickness of the tunnel dielectric layer 5a is between 5-15 nm, generally 10 nm. The source insulating layer 5b is formed on the main doped region of the source. A thickness of the source insulating layer 5b is between 10-50 nm, generally 20 nm. The tunnel dielectric layer 5a is contiguous to the source insulating layer 5b.

The select gate 3 is formed on the first dielectric layer 13. The first insulating layer 4 is formed on the select gate 3. The floating gate 8 is formed on the tunnel dielectric layer 5a. A portion of the floating gate 8 is located on a portion of the source insulating layer 5b, which, in turn, is located on the lightly-doped region 10a of the source diffusion region 10. The floating gate 8 is spaced from the select gate 3 and the first insulating layer 4 by a sidewall insulating layer 17 (generally a composite layer made of silicon dioxide or made of silicon dioxide and silicon nitride) and is formed on a side of the sidewall insulating layer 17. A thickness of the sidewall insulating layer 17 is 10-30 nm, preferably 20 nm. A second dielectric layer 11 (generally a composite layer made of silicon dioxide and silicon nitride) is formed on the floating gate 8 and the first insulating layer 4. A thickness of the second dielectric layer 11 is 10-20 nm.

The control gate 12 generally has a thickness of 100 nm. At least a portion of the control gate 12 is formed on the floating gate 8. Furthermore, the control gate 12 and the floating gate 8 are insulating to each other by the second dielectric layer 11.

As shown in FIG. 1, the floating gate 8 is electrically insulating and is without electrical connection with the outside. However, by controlling the voltage of the control gate 12, the voltage of the floating gate 8 can indirectly be controlled by capacitor coupling.

Since the floating gate 8 of the non-volatile memory unit is located on the source diffusion region (heavily doped) 10 and the lightly-doped region 10a of the source diffusion region 10, when the non-volatile memory unit undergoes an erasing operation, the source diffusion region 10 is spaced from the floating gate 8 by the thicker source insulating layer 5b, and the lightly-doped region 10a is spaced from the floating gate 8 by the tunnel dielectric layer 5a and undergoes electron tunneling, such that the source leakage effect between the floating gate 8 and the p-typed silicon substrate 1 can effectively be reduced to reduce the current supply demand of the power source, permitting easy achievement of integration of the whole circuit. Furthermore, in the structure of this split-gate type non-volatile memory unit, the thicker source insulating layer 5b can permit multiple polycrystalline silicon etching for forming the floating gate and can protect the drain diffusion surface and the source diffusion surface. The integrity of the non-volatile memory unit can be maintained during more etching processing for removing the residuals of polycrystalline silicon between the floating gates. Furthermore, this improvement also permits the area of the non-volatile memory unit to be further reduced under cooperation with advanced processes, further reducing the costs and increasing the yield.

An example of a method for producing the non-volatile memory unit will now be set forth.

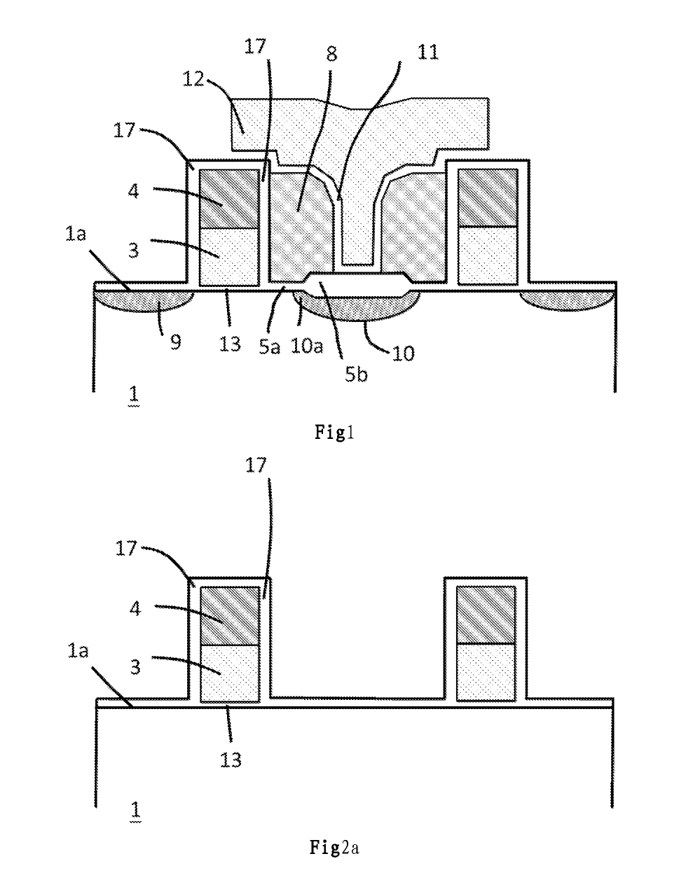

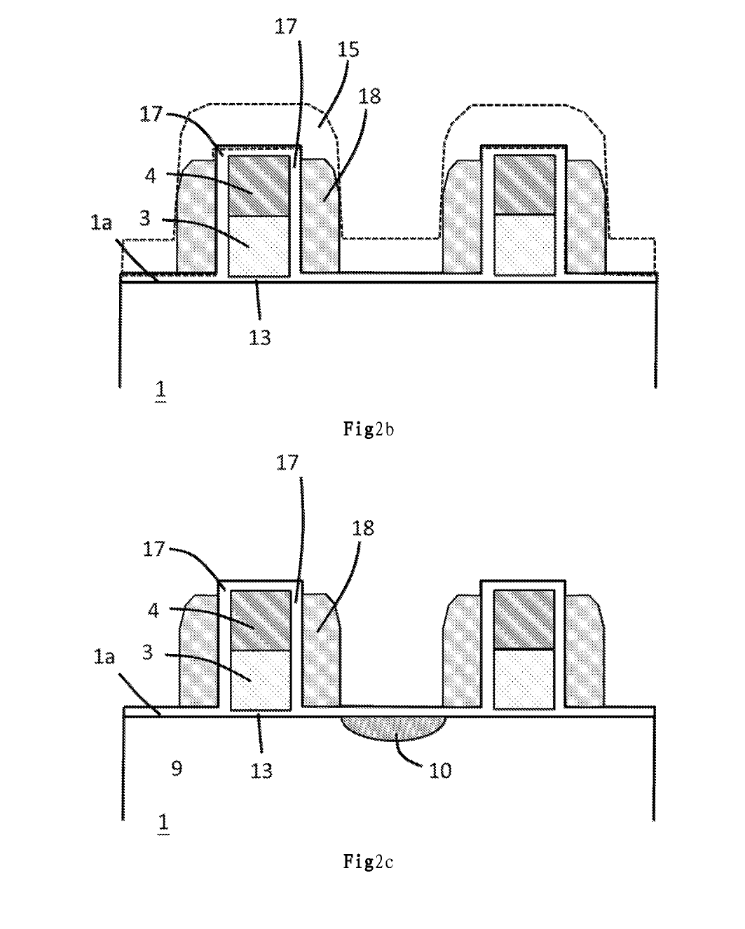

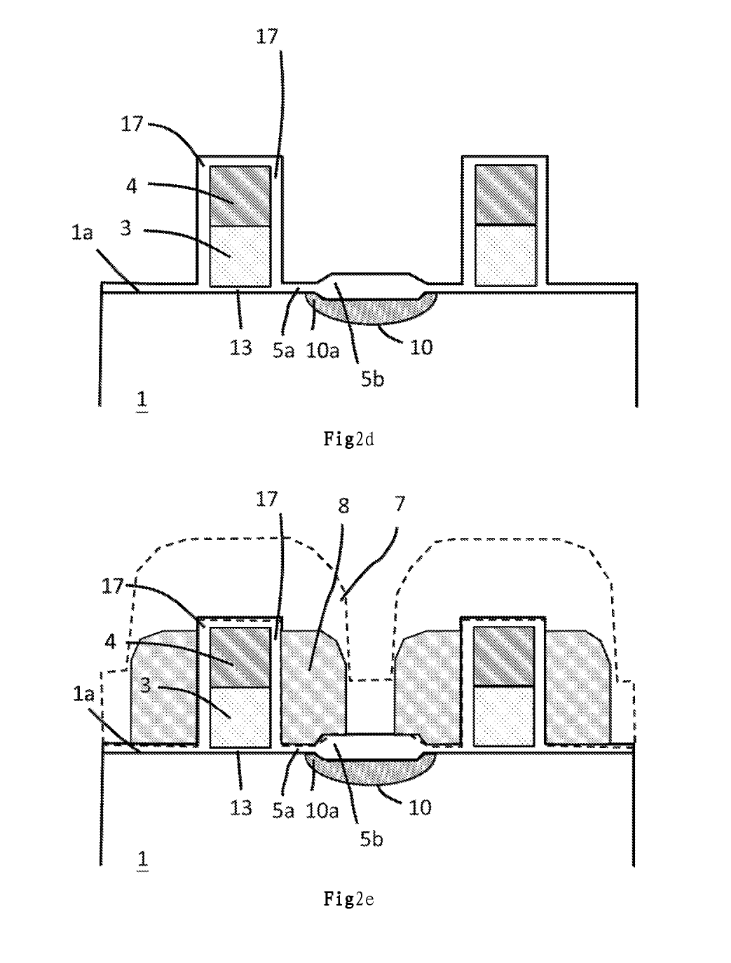

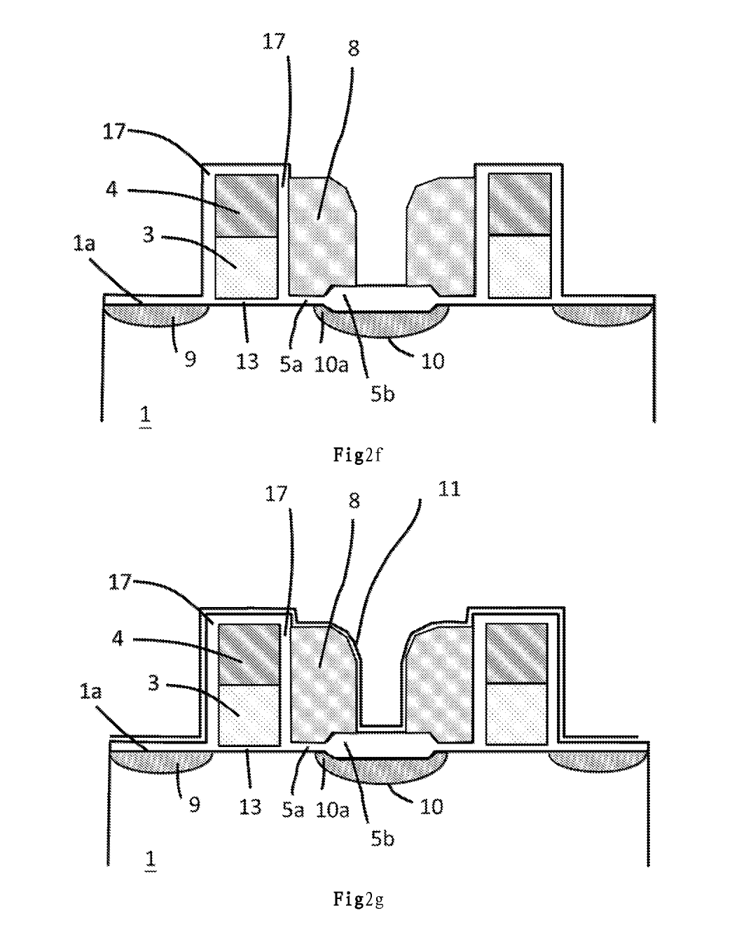

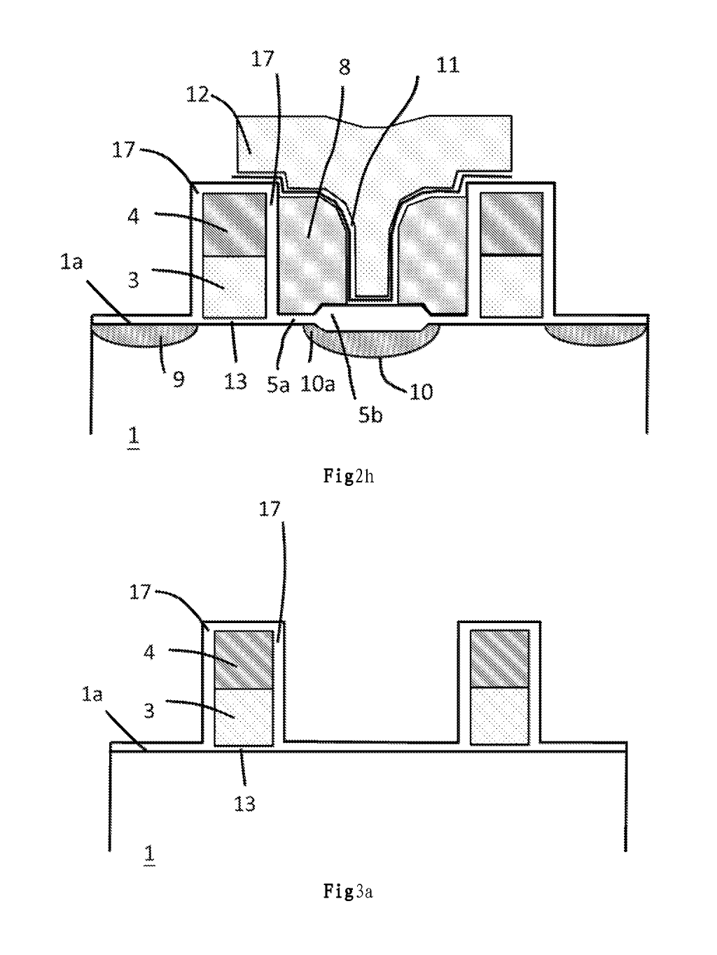

FIGS. 2a-2h are diagrammatic views illustrating an example of the method for producing the non-volatile memory unit disclosed in the present invention, which can be used in production of a non-volatile memory unit. This example includes the following steps.

As shown in FIG. 2a, a substrate, such as a p-type silicon substrate 1, is prepared. The p-type silicon substrate 1 has an upper surface 1a.

As shown in FIG. 2a, a first dielectric layer 13 is formed on the upper surface 1a of the p-type silicon substrate 1 by thermal oxidation or any other oxidation. The first dielectric layer 13 is generally a gate oxidation layer of silicon dioxide or any other high-k dielectric layer. The first dielectric layer 13 has a thickness of 1-10 nm.

As shown in FIG. 2a, a select gate 3 and a first insulating layer 4 are formed on the first dielectric layer 13. Specifically, a 100 nm polycrystalline silicon layer and a 100 nm insulating layer are formed on the whole face of the first dielectric layer 13 in sequence. The material for the insulating layer can be silicon nitride (SiN) or tetraethyl orthosilicate (TEOS). Next, an etch blocking pattern layer is formed on the insulating layer. After formation of the etch blocking pattern layer, selective etching is carried out to etch away a portion of the polycrystalline silicon layer and the insulating layer to form the select gate 3 and the first insulating layer 4.

As shown in FIG. 2a, the etch blocking pattern layer is removed, and a high-temperature oxide (HTO) deposition process is used to form a SiO₂ insulating layer on the whole face of the p-type silicon substrate 1 already having the select gate 3 and the first insulating layer 4. The SiO₂ insulating layer can combine with a SiN barrier layer (10-20 nm) to form a composite layer covering the sidewall faces of the select gate 3 and the first insulating layer 4. The SiO₂ insulating layer covers an exposed portion of the SiO₂ gate oxidation layer, a side of the select gate 3, and a side of the first insulating layer 4 as well as the top face of the first insulating layer 4. A thickness of the SiO₂ insulating layer is 10-30 nm. The SiO₂ insulating layer forms a SiO₂ layer or the above sidewall insulating layer 17 on the sidewall portions of the select gate 3 and the first insulating layer 4. The cross sectional view of the non-volatile memory unit by now is shown in FIG. 2a.

As shown in FIG. 2b, a uniformly covering barrier layer 15 (generally made of silicon nitride or silicon oxide) is selectively etched to form a barrier layer 18 covering the sidewalls of the sidewall insulating layer 17. The sidewall barrier layer 18 has a thickness of 20-200 nm, preferably 100 nm. The cross sectional view of the non-volatile memory unit is shown in FIG. 2b.

As shown in FIG. 2c, by using implantation, N-type atoms (preferably arsenic atoms) are doped into a side of the select gate 3 and a side of the first insulating layer 4 to form an n-type doped region. The doping concentration is 10¹³-10¹⁶/cm³. The doped region can be a gradually doped structure which is then subject to rapid thermal annealing and serves as a source 10.

As shown in FIG. 2d, the sidewall barrier layer 18 is removed, and the residual oxidation layer and the insulating layer on the upper surface 1a of the substrate 1 are then removed. Next, a tunnel dielectric layer 5a is formed on the upper surface 1a of the substrate 1 by thermal oxidation or in situ steam generation (ISSG). The tunnel dielectric layer 5a has a thickness of 5-15 nm.

As shown in FIG. 2d, during formation of the tunnel dielectric layer 5a, since source doping provides silicon oxide with doping enhanced oxidation, a thicker source insulating layer 5b is formed on the source doped region and has a thickness of 15-100 nm. Furthermore, the defects caused by ion implantation can be repaired by the source doping-enhanced thermal oxidation which forms the source insulating layer 5b, and the source doping automatically diffuses to form a lightly-doped region 10a (source lightly n-doped diffusion). When the non-volatile memory unit undergoes an operation of writing “1”, the tunneling of hot electron current occurs in the tunnel dielectric layer 5a. Thus, the tunnel dielectric layer 5a having a different thickness and the self-aligned source lightly-heavily doped structure can effectively reduce the leakage between the source bands during the erasing operation, increasing the tunneling efficiency and its uniformity, which assists in increasing the yield of the non-volatile memory unit. The cross sectional view of the non-volatile memory unit by now is shown in FIG. 2d.

As shown in FIG. 2e, a polycrystalline silicon layer 7 is formed on the face of the structure of FIG. 2d. The polycrystalline silicon layer 7 has a thickness of 20-200 nm, preferably about 100 nm. Reactive ion etching (RIE) is carried out on the polycrystalline silicon layer 7 and is highly directional. Only a portion of the resultant polycrystalline silicon layer 7 at the sides of the select gate 3 and the first insulating layer 4 is left. The cross sectional view of the non-volatile memory unit by now is shown in FIG. 2e.

As shown in FIG. 2f, an etch blocking pattern layer is formed on the face of the structure shown in FIG. 2e. After formation of the etch blocking pattern layer, selective etching is carried out to define a floating gate. A portion of the polycrystalline silicon layer 7 at the other sides of the select gate 3 and the first insulating layer 4 is etched. The remaining portion of the polycrystalline silicon layer 7 forms a floating gate 8 located on the tunnel dielectric layer 5a and the source insulating layer 5b.

As shown in FIG. 2f, another doped region is formed in other side of the substrate opposite to the select gate to form a drain. For example, n-type atoms are doped into the p-type silicon substrate 1 by ion implantation. The region at the other sides of the select gate 3 and the first insulating layer 4 is a drain diffusion region 9. The cross sectional view of the non-volatile memory unit by now is shown in FIG. 2f.

As shown in FIG. 2g, an oxide/nitride/oxide (ONO) dielectric layer is formed on the structure of FIG. 2f and serves as a second dielectric layer 11. The second dielectric layer 11 has a thickness of 10-20 nm, preferably 15 nm.

As shown in FIG. 2h, a control gate 12 is formed on the second dielectric layer 11. A portion of the control gate 12 is located in a space of a channel structure of the second dielectric layer 11. For example, a polycrystalline silicon layer is formed on the whole face of the second dielectric layer 11 and has a thickness of 100 nm. Next, another etch blocking pattern layer is formed, and selective etching is carried out. The remaining polycrystalline silicon layer defines a control gate 12. The control gate 12 mainly covers the floating gate 8. Then, the etch blocking pattern layer is removed. The main structure of the non-volatile memory unit is accomplished by now, and its cross sectional view is shown in FIG. 2h.

Another example of the method for producing the non-volatile memory unit will now be set forth.

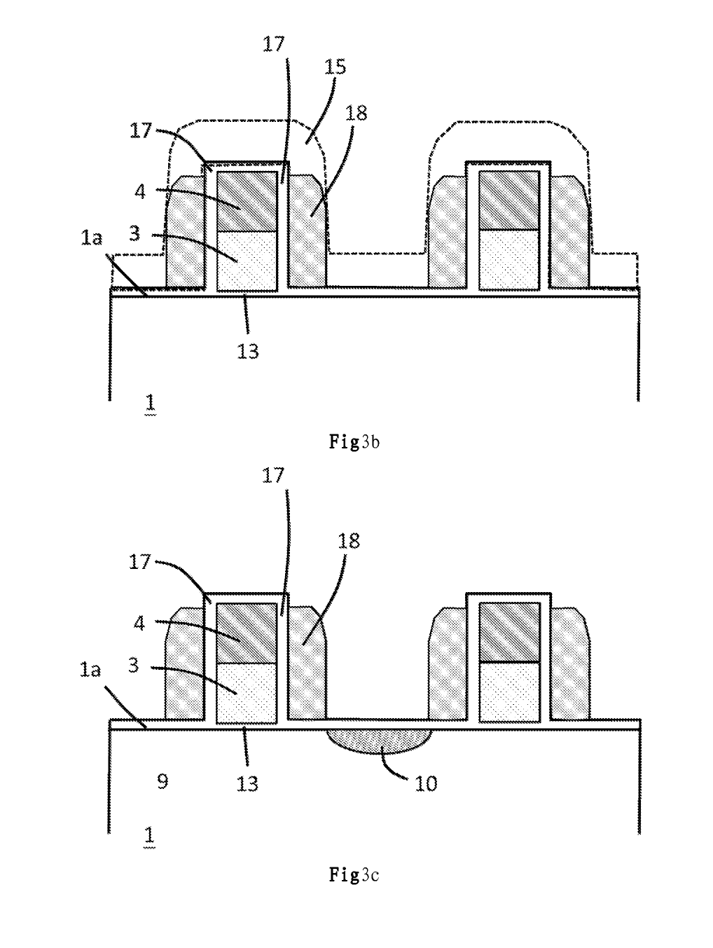

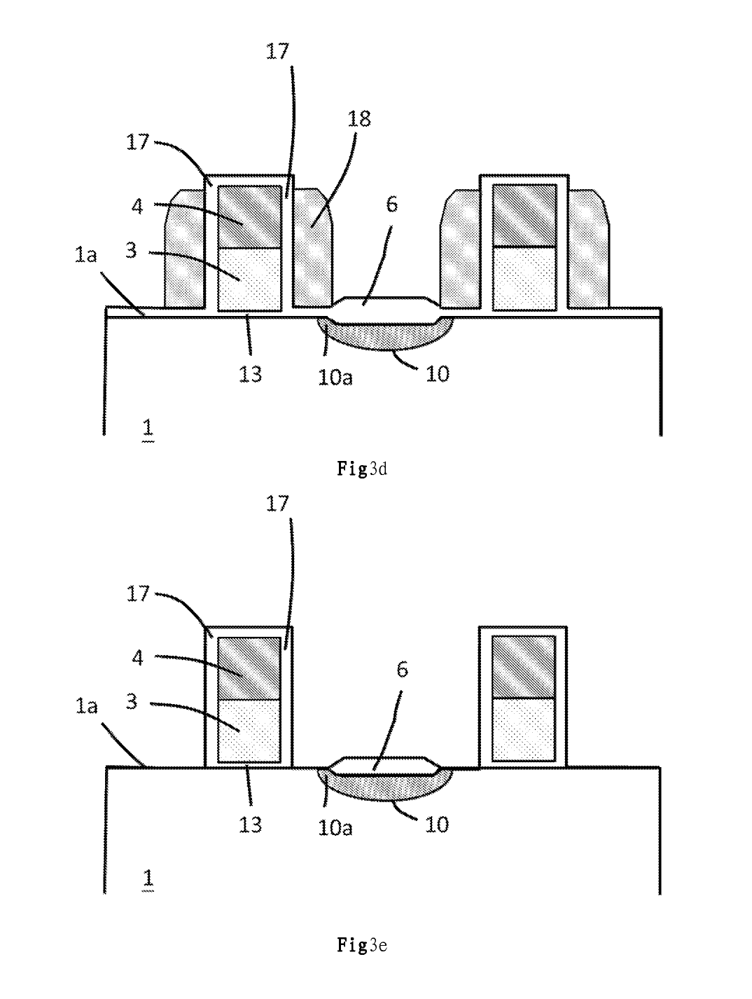

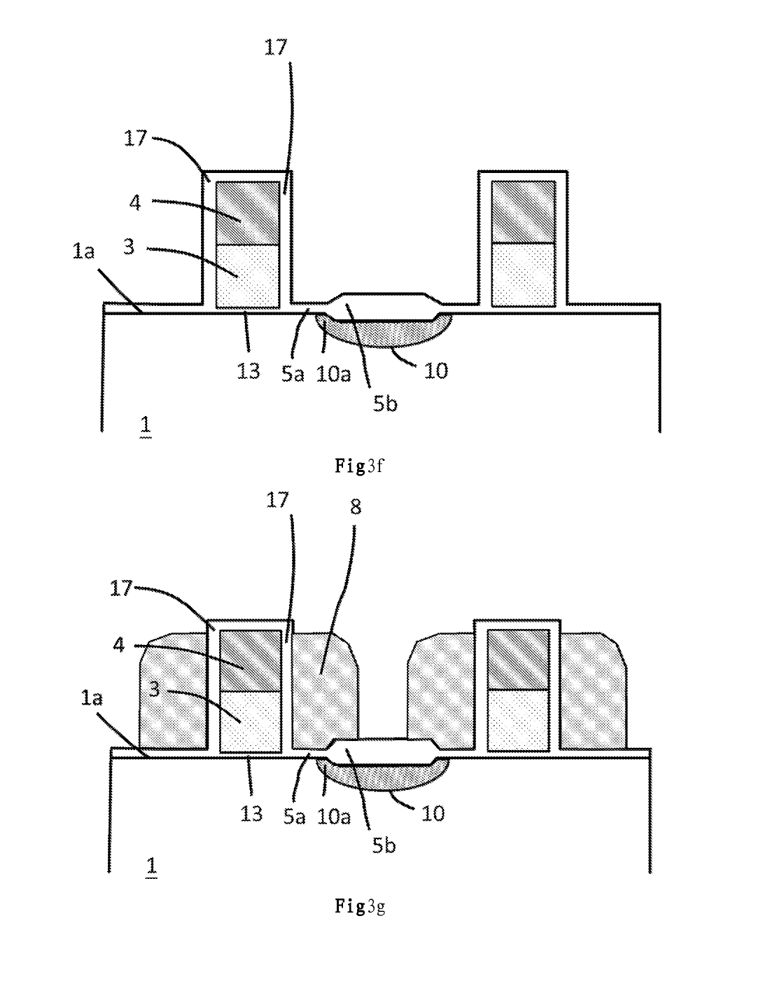

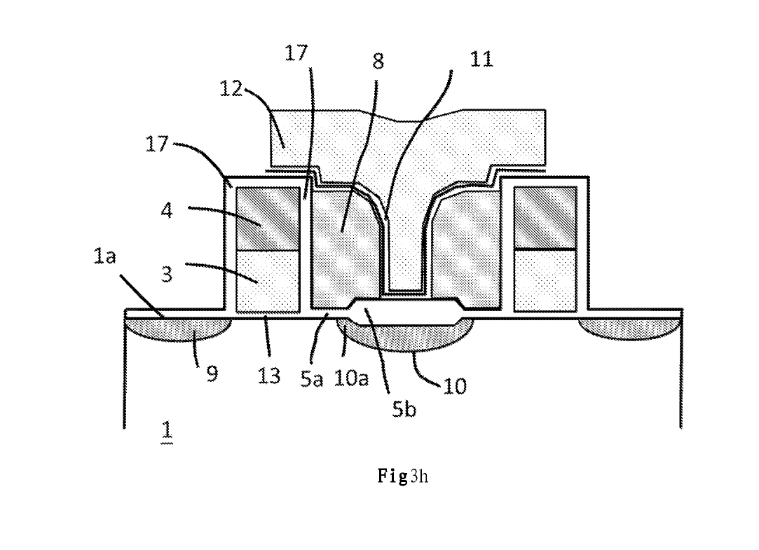

The formation step shown in FIG. 3a is the same as that shown in FIG. 2a. Please refer to the corresponding description in connection with FIG. 2a.

The formation step shown in FIG. 3b is the same as that shown in FIG. 2b. Please refer to the corresponding description in connection with FIG. 2b.

The formation step shown in FIG. 3c is the same as that shown in FIG. 2c. Please refer to the corresponding description in connection with FIG. 2c.

As shown in FIG. 3d, a thicker source insulating layer 5b is formed on the upper surface 1a of the substrate 1 by thermal oxidation or in situ steam generation (ISSG) without removing the sidewall barrier layer 18. The source insulating oxide 5b has a thickness of 15-100 nm because of doping enhanced oxidation. Furthermore, the defects caused by ion implantation can be repaired by the source doping-enhanced thermal oxidation which forms the source insulating layer 5b, and the source doping automatically diffuses to form a lightly-doped region 10a (source lightly n-doped diffusion).

As shown in FIG. 3e, the sidewall barrier wall 18 is removed, and the residual oxidation layer and the insulating layer on the upper surface 1a of the substrate 1 are then removed.

As shown in FIG. 3f, a tunnel dielectric layer 5a is formed on the upper surface 1a of the substrate 1 by thermal oxidation or in situ steam generation (ISSG). The tunnel dielectric layer 5a has a thickness of 5-15 nm adjacent to the source insulating layer 5b. When the non-volatile memory unit undergoes an operation of writing “1”, the tunneling of hot electron current occurs in the tunnel dielectric layer 5a. Thus, the tunnel dielectric layer 5a having a different thickness and the self-aligned source lightly-heavily doped structure can effectively reduce the leakage between the source bands during the erasing operation, increasing the tunneling efficiency and its uniformity, which assists in increasing the yield of the non-volatile memory unit. The cross sectional view of the non-volatile memory unit by now is shown in FIG. 3f.

The formation step shown in FIG. 3g is the same as that shown in FIG. 2e. Please refer to the corresponding description in connection with FIG. 2e.

The formation step shown in FIG. 3h is the same as that shown in FIG. 2h. Please refer to the corresponding description in connection with FIG. 2h. The main structure of the non-volatile memory unit is accomplished by now, and its cross sectional view is shown in FIG. 3h.

Operation of the non-volatile memory unit will now be set forth.

During the erasing operation, i.e., when the non-volatile memory unit undergoes the operation of writing “1”, a voltage of 6V is applied to the source diffusion region 10, a voltage of −9V is applied to the control gate 12, and a voltage of 0V is applied to the drain diffusion region 9 and the select gate 3. Since an equivalent capacitor exists between the floating gate 8 and the control gate 12, the capacitance of the equivalent capacitor is far larger than the capacitance of an equivalent capacitor between the floating gate 8 and the source diffusion region 10. Thus, most of a voltage difference applied between the control gate 12 and the source diffusion region 10 will be reflected on the voltage difference between the floating gate 8 and the source diffusion region 10. Namely, the voltage of the floating gate 8 is about −8V. According to the principle of Fowler-Nordheim tunneling, the electrons will tunnel through the tunnel dielectric layer 5a at the bottom of the floating gate 8 into the source diffusion region 10, and the final equivalent polarity of the floating gate 8 is positive.

Since the voltage difference between the source diffusion region 10 and the control gate 12 is as high as 14V and since the source diffusion region 10 has a higher voltage, band-to-band tunneling (or referred to as gate-induced drain leakage (GIDL)) is triggered, leading to a breakdown voltage between the source diffusion region 10 and the p-typed silicon substrate 1. The magnitude of the leakage current depends on the electric field intensity between the source diffusion region 10 and the p-typed silicon substrate 1. In the non-volatile memory unit according to the present invention, since the source diffusion region 10 has a larger space extending in the transverse direction and forms a lightly-doped source, the electric field intensity can effectively be reduced to greatly reduce the magnitude of the leakage current, increasing the utility efficiency of the power source and reducing the temperature increase during operation of the circuit. The service life of the circuit is, thus, prolonged.

During the operation of writing “0”, a voltage of 5-6V is applied to the source diffusion region 10, a voltage of 9V is applied to the control gate 12, a voltage of 0-0.5V is applied to the drain diffusion region 9, and a voltage of about 1V is applied to the select gate 3. The voltage of 1V is slightly higher than the threshold voltage of an equivalent transistor component of the non-volatile memory unit, such that the equivalent transistor component is in a conductive state. This conductive state causes the equivalent transistor component of the non-volatile memory unit to conduct a micro ampere (μA) current. This current flows from the source diffusion region 10, flows in the p-type silicon substrate 1 along the channel portion of the tunnel dielectric layer 5a, takes a quarter turn at below the first dielectric layer 13, and flows into the drain diffusion region 9 via the channel portion below the select gate 3. The electrons flow in a reverse direction opposite to the current. In this case, the floating gate is in a state having a higher voltage due to the bias of the control gate 12, such that the tunnel dielectric layer 5a below the floating gate 8 is also in a state having a higher voltage. However, the voltage at the channel portion below the first dielectric layer 13 is lower due to the conductive state of the equivalent transistor component. Thus, when the electrons flow through the channel portion below the first dielectric layer 13 into the channel portion of the tunnel dielectric layer 5a, the corresponding voltage change (about 5V) creates a high electric field which triggers the mechanism of hot electron injection. Most of the electrons will flow from the high electric field through the tunnel dielectric layer 5a (tunneling) into the floating gate 8. Finally, the equivalent polarity of the floating gate 8 turns into negative after the floating gate 8 has trapped a sufficient amount of electrons.

During reading operation, a voltage of 0V is applied to the source diffusion region 10 and the control gate 12 (or a voltage of Vcc is applied to the control gate 12, Vcc is the power supply voltage of the memory circuit and is generally 1.8V in a 0.18 μm process), a voltage of about 1V is applied to the drain diffusion region 9, and a voltage of Vcc is applied to the select gate 3. In this case, the channel portion below the select gate 3 is in a conductive state. Assume that the storage state of the non-volatile memory unit is “0” (namely, the polarity of the floating gate 8 is negative), the channel portion of the tunnel dielectric layer 5a below the floating gate 8 is not in the conductive state (namely, the magnitude of the current in the channel portion is almost 0). On the other hand, assume that the storage state of the non-volatile memory unit is “1” (namely, the polarity of the floating gate 8 is positive), the channel portion of the tunnel dielectric layer 5a below the floating gate 8 is also in the conductive state. In this case, a current of about 30 μA exists in the channel. The storage content in the non-volatile memory unit can be known by detecting the magnitude of the current in the channel.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. A non-volatile memory unit comprising:
a substrate including an upper surface, with the substrate further including a source diffusion region and a drain diffusion region in the substrate;
a first dielectric layer formed on the upper surface of the substrate and located on the drain diffusion region side;
a tunnel dielectric layer formed on the upper surface of the substrate and located on the source diffusion region side, with the tunnel dielectric layer including a lower face covering a portion of the source diffusion region;
a source insulating layer formed on an upper surface of the source diffusion region of the substrate, with the source insulating layer including a lower face, with an entire area of the lower face of the source insulating layer covering the source diffusion region;
a select gate formed on the first dielectric layer;
a floating gate formed on a face of the tunnel dielectric layer and a face of the source insulating layer, with a portion of the floating gate located on the tunnel dielectric layer covering a portion of the source diffusion region;
a second dielectric layer formed on a face of the floating gate; and
a control gate formed on the floating gate, with the control gate and the floating gate being insulating to each other by the second dielectric layer.

2. The non-volatile memory unit as claimed in claim 1, wherein the source diffusion region is a gradually diffused doped structure.

3. The non-volatile memory unit as claimed in claim 1, wherein the first dielectric layer has a thickness of 0.5-10 nm.

4. The non-volatile memory unit as claimed in claim 1, wherein the tunnel dielectric layer has a thickness of 5-15 nm.

5. The non-volatile memory unit as claimed in claim 1, wherein the source insulating layer has a thickness of 10-30 nm and is thicker than a thickness of the tunnel dielectric layer.

6. A method for producing a non-volatile memory unit, comprising:
providing a substrate, with the substrate including an upper surface;
forming a first dielectric layer on the upper surface of the substrate;
forming a select gate on the first dielectric layer;
forming a select gate sidewall insulating layer, and forming a tunnel dielectric layer on the upper surface of the substrate at a location not covered by the select gate;
forming a self-aligned source dope blocking layer;
forming a source diffusion region by doping;
removing the self-aligned source dope blocking layer;
forming a tunnel dielectric layer and a source insulating layer on a face of the source doped region by silicon oxidation, with the source insulating layer thicker than the tunnel dielectric layer, with a lightly-doped region of the source diffusion region formed at a junction between the tunnel dielectric layer and the source insulating layer and covering a portion of the tunnel dielectric layer;
forming a self-aligned floating gate on the tunnel dielectric layer and the source insulating layer;
forming a second dielectric layer on the floating gate; and
forming a control gate on the second dielectric layer, with a portion of the control gate located in a space of a channel structure of the second dielectric layer.

7. The method for producing a non-volatile memory unit as claimed in claim 6, wherein the source diffusion region is a gradually diffused doped structure.

8. The method for producing a non-volatile memory unit as claimed in claim 6, wherein the first dielectric layer has a thickness of 0.5-10 nm.

9. The method for producing a non-volatile memory unit as claimed in claim 6, wherein the tunnel dielectric layer has a thickness of 5-12 nm.

10. The method for producing a non-volatile memory unit as claimed in claim 6, wherein the source insulating layer has a thickness of 10-30 nm and is thicker than a thickness of the tunnel dielectric layer.

11. A method for producing a non-volatile memory unit, comprising:
providing a substrate, with the substrate including an upper surface;
forming a first dielectric layer on the upper surface of the substrate;
forming a select gate on the first dielectric layer;
forming a select gate sidewall insulating layer, and forming a tunnel dielectric layer on the upper surface of the substrate at a location not covered by the select gate;
forming a self-aligned source dope blocking layer;
forming a source diffusion region by doping;
forming a source insulating layer on a face of the source doped region by silicon oxidation;
removing the self-aligned source dope blocking layer;
forming a tunnel dielectric layer, with a lightly-doped region of the source diffusion region formed at a junction between the tunnel dielectric layer and the source insulating layer and covering a portion of the tunnel dielectric layer;
forming a self-aligned floating gate on the tunnel dielectric layer and the source insulating layer;
forming a second dielectric layer on the floating gate; and
forming a control gate on the second dielectric layer, with a portion of the control gate located in a space of a channel structure of the second dielectric layer.

12. The method for producing a non-volatile memory unit as claimed in claim 11, wherein the source diffusion region is a gradually diffused doped structure.

13. The method for producing a non-volatile memory unit as claimed in claim 11, wherein the first dielectric layer has a thickness of 0.5-10 nm.

14. The method for producing a non-volatile memory unit as claimed in claim 11, wherein the tunnel dielectric layer has a thickness of 5-12 nm.

15. The method for producing a non-volatile memory unit as claimed in claim 11, wherein the source insulating layer has a thickness of 10-30 nm and is thicker than a thickness of the tunnel dielectric layer.
